(19) United States
(12) Patent Application Publication
(10) Pub. No.: US 2007/0026596 A1
(43) Pub. Date: Feb. 1, 2007

(54) Gate electrode structure and method of forming the same, and semiconductor transistor having the gate electrode structure and method of manufacturing the same

(75) Inventors: Hag-Ju Cho, Seoul (KR); Taek-Soo Jeon, Yongin-si (KR); Hye-Lan Lee, Hwaseong-si (KR); Yu-Gyun Shin, Seongnam-si (KR); Sang-Bom Kang, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/492,400

(22) Filed: Jul. 25, 2006

(30) Foreign Application Priority Data
Jul. 26, 2005 (KR) 10-2005-0068050

(51) Int. Cl. H01L 21/8234

(52) U.S. Cl. 438/197

(57) ABSTRACT

In a gate structure and a method of forming the same, a first conductive pattern is formed on a substrate and comprises a metal-containing material. A second conductive pattern is formed on the first conductive pattern, and the second conductive pattern comprises metal and silicon. A third conductive pattern is formed on the second conductive pattern, and the third conductive pattern comprises polysilicon. A gate conductive pattern of an n-type metal-oxide semiconductor (NMOS) transistor, a p-type MOS (PMOS) transistor and a complementary MOS (CMOS) transistor includes the gate structure. The second conductive pattern is interposed between the first and third conductive patterns and the third conductive pattern is prevented from making direct contact with the first conductive pattern, so that polysilicon in the third conductive pattern is sufficiently prevented from being chemically reacted with the metal in the first conductive pattern in advance, thereby improving electrical characteristics of the transistor.

### CROSS-REFERENCE TO RELATED APPLICATIONS

This application claims priority to Korean Patent Application No. 2005-68050 filed on Jul. 26, 2005, the content of which is herein incorporated by, reference in its entirety.

### BACKGROUND OF THE INVENTION

1. Field of the Invention

Example embodiments of the present invention relate to a gate electrode structure and a method of forming the same, and a semiconductor transistor having the same gate electrode structure and a method of manufacturing the same. More particularly, example embodiments of the present invention relate to a semiconductor transistor including a gate electrode structure comprising a conductive material including metal and silicon.

2. Description of the Related Art

A gate insulation layer of a highly-integrated semiconductor device commonly includes a high dielectric constant material, or “a high-k” material, because a gate insulation layer comprising the high-k material can sufficiently minimize current leakage between a gate conductive layer and a channel in a gate structure, and has a relatively small equivalent oxide thickness (EOT). Examples of high-k materials include hafnium oxide (HfO₂), titanium oxide (TiO₂), zirconium oxide (ZrO₂), aluminum oxide (Al₂O₃) and tantalum oxide (Ta₂O₅).

When a polysilicon layer is formed on the gate insulation layer comprising a metal oxide as the gate conductive layer, the polysilicon of the gate conductive layer chemically reacts with metal oxide of the gate insulation layer in a subsequent process, so that byproducts of the chemical reaction of metal and silicon, such as silicon oxide are produced at a boundary surface of the gate insulation layer and the gate conductive layer. The silicon oxide at the boundary surface of the gate insulation layer and the gate conductive layer causes a transition of a threshold voltage that is widely known as Fermi level pinning. Dopants in a substrate are prevented from moving due to the Fermi level pinning, and thus a flat-band voltage V_{fb}, which is proportional to the threshold voltage, is difficult to accurately control.

Research has confirmed advantages of a metal-containing material when the metal-containing material is utilized in a manufacturing process for a semiconductor device. In particular, a metal-containing material substituting for polysilicon in the gate conductive layer may sufficiently reduce the Fermi level pinning, and no polysilicon depletion is generated in the case where the gate insulation comprises the metal-containing material in place of polysilicon, thereby sufficiently preventing an increase of the EOT of the gate insulation layer caused by the polysilicon depletion. Furthermore, the metal-containing material may also sufficiently reduce charge trapping and remote charge scattering, leading to improved operation speed in the semiconductor device including the gate insulation layer. The metal-containing material in the gate insulation layer may also function as a diffusion barrier in a subsequent ion implantation process for formation of source/drain regions.

For the above reasons, a semiconductor device of a high integration degree usually includes a gate insulation layer comprising a high-k material, such as a metal oxide and a gate conductive layer comprising a metal-containing material.

U.S. Pat. Nos. 6,518,106 and 6,552,377 disclose a gate pattern including a gate insulation layer comprising a metal oxide and a gate conductive layer comprising a metal-containing material.

However, according to U.S. Pat. No. 6,518,106, while the gate conductive layer of an n-type metal-oxide semiconductor (NMOS) transistor comprises polysilicon, the gate conductive layer of a p-type MOS (PMOS) transistor comprises a metal-containing material, so that the NMOS transistor does not have the above-mentioned advantages of metal-containing material. According to U.S. Pat. No. 6,552,377, the gate conductive layer both of an NMOS transistor and a PMOS transistor comprise a metal-containing material, so that the gate conductive layer disclosed in U.S. Pat. No. 6,552,377 sufficiently has the above-mentioned advantages of metal-containing material. However, the transistor disclosed in U.S. Pat. No. 6,552,377 has a problem in that the gate conductive layer including a metal-containing material is exposed to the external environment, and a surface of the gate conductive layer tends to be easily oxidized and deformed by an external stress.

Accordingly, the gate conductive layer of a contemporary semiconductor device typically includes a metal-containing material together with polysilicon in such a structure that a polysilicon layer is stacked on a material layer comprising the metal-containing material. Thus, the gate conductive layer including the metal-containing material and polysilicon has the above-mentioned advantages of the metal-containing material. In addition, the polysilicon layer can absorb an external stress applied to the gate conductive layer and prevents the metal-containing material from becoming oxidized.

However, the above stacked structure of the polysilicon layer on the metal-containing material layer has a problem in that polysilicon in the polysilicon layer chemically reacts with the metal-containing material in the material layer. Particularly, when a pure metal in the metal-containing material is chemically reacted with polysilicon, an undesirable metal silicide layer is formed on a boundary surface of the metal-containing material layer and the polysilicon layer, so that a void is generated in the polysilicon layer, thereby reducing reliability of the gate conductive layer. In addition, when a metal nitride in the metal-containing material is chemically reacted with polysilicon, a nitride is produced on the boundary surface of the metal-containing material layer and the polysilicon layer, thereby remarkably increasing the electrical resistance of the gate conductive layer.

### SUMMARY OF THE INVENTION

Accordingly, example embodiments of the present invention provide a gate structure including a metal-containing material without any chemical reaction with polysilicon.

Example embodiments of the present invention provide an n-type metal-oxide semiconductor (NMOS) transistor including the above gate structure.

Example embodiments of the present invention provide a p-type MOS (PMOS) transistor including the above gate structure.

Example embodiments of the present invention provide a complementary MOS (CMOS) transistor including the above gate structure.

Example embodiments of the present invention provide a method of forming the above gate structure.

Example embodiments of the present invention provide a method of forming the above NMOS transistor.

Example embodiments of the present invention provide a method of forming the above PMOS transistor.

Example embodiments of the present invention provide a method of forming the above CMOS transistor.

According to an aspect of the present invention, there is provided a gate structure includes a first conductive pattern comprising a metal-containing material, a second conductive pattern comprising metal and silicon on the first conductive pattern, and a third conductive pattern comprising polysilicon on the second conductive pattern.

In one embodiment, the metal in the first conductive pattern is substantially identical to the metal in the second conductive pattern.

In another embodiment, the second conductive pattern includes a metal silicide thin layer artificially formed by one of a chemical vapor deposition (CVD) process, a sputtering process and a silicidation process.

In another embodiment, the second conductive pattern includes a metal silicide thin layer formed by one of a chemical vapor deposition (CVD) process, a sputtering process and a silicidation process.

In another embodiment, a thickness of the first conductive pattern is about 0.3 to about 10 times a thickness of the second conductive pattern, and a thickness of the third conductive pattern is about 8.0 to about 75.0 times the thickness of the second conductive pattern.

In another embodiment, the first conductive pattern has a thickness of about 30 Å to about 200 Å, the second conductive pattern has a thickness of about 20 Å to about 100 Å, and the third conductive pattern has a thickness of about 500 Å to about 1,500 Å.

In another embodiment, the metal-containing material of the first conductive pattern includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

According to an aspect of the present invention, there is provided an NMOS transistor including a semiconductor substrate, source/drain regions doped with n-type impurities at a first surface portion of the substrate, a channel region at a second surface portion of the substrate between the source/drain regions, and a gate pattern on the channel region. In an example embodiment of the present invention, the gate pattern includes a gate insulation pattern and a gate conductive pattern, and the gate conductive pattern includes a first conductive pattern comprising a metal-containing material, a second conductive pattern comprising metal and silicon on the first conductive pattern, and a third conductive pattern comprising polysilicon on the second conductive pattern.

According to an aspect of the present invention, there is provided a PMOS transistor including a semiconductor substrate, source/drain regions doped with p-type impurities at a first surface portion of the substrate, a channel region at a second surface portion of the substrate between the source/drain regions, and a gate pattern on the channel region. In an example embodiment of the present invention, the gate pattern including a gate insulation pattern and a gate conductive pattern, and the gate conductive pattern includes a first conductive pattern comprising a metal-containing material, a second conductive pattern comprising metal and silicon on the first conductive pattern, and a third conductive pattern comprising polysilicon on the second conductive pattern.

In one embodiment, a metal in the first conductive pattern is substantially identical to the metal in the second conductive pattern.

In another embodiment, the second conductive pattern includes a metal silicide thin layer formed by one of a CVD process, a sputtering process and a silicidation process.

In another embodiment, the first conductive pattern has a thickness of about 30 Å to about 200 Å, the second conductive pattern has a thickness of about 20 Å to about 100 Å, and the third conductive pattern has a thickness of about 500 Å to about 1,500 Å.

In another embodiment, the metal-containing material of the first conductive pattern includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

In another embodiment, the n-type impurities include any one selected from the group consisting of phosphorus (P), arsenic (As) and a combination thereof.

In another embodiment, the gate insulation pattern comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof.

In another embodiment, the p-type impurities include boron (B).

According to an aspect of the present invention, there is provided a CMOS transistor including a semiconductor substrate including a first area and a second area and an NMOS transistor on the first area of the substrate and a PMOS transistor on the second area of the substrate. The NMOS transistor includes first source/drain regions doped with n-type impurities at a first surface portion of the first area of the substrate, a first channel region at a second surface portion of the first area of the substrate between the first source/drain regions, and a first gate pattern having a first gate insulation pattern and a first gate conductive pattern and positioned on the first channel region, and the PMOS transistor includes second source/drain regions doped with p-type impurities at a first surface portion of the second area of the substrate, a second channel region at a second surface portion of the second area of the substrate between the second source/drain regions and a second gate pattern having a second gate insulation pattern and a second gate conductive pattern and positioned on the second channel region. In an example embodiment of the present invention, the first gate conductive pattern includes a first conductive pattern comprising a metal-containing material, a second conductive pattern comprising metal and silicon on the first conductive pattern, and a third conductive pattern comprising polysilicon on the second conductive pattern, and the second gate conductive pattern includes a fourth conductive pattern comprising a metal-containing material, a fifth conductive pattern comprising metal and silicon on the fourth conductive pattern and a sixth conductive pattern comprising polysilicon on the fifth conductive pattern.

According to an aspect of the present invention, there is provided a method of forming the gate structure. A first conductive layer comprising a metal-containing material is formed on a substrate, and a second conductive layer is artificially formed on the first conductive layer by a CVD process or a silicidation process. The second conductive layer comprises metal and silicon. A third conductive layer is formed on the second conductive layer, and the third conductive layer comprises polysilicon. The third conductive layer, the second conductive layer and the first conductive layer are sequentially patterned by a photolithography process, thereby forming a first conductive pattern, a second conductive pattern and a third conductive pattern sequentially stacked on the substrate.

According to an aspect of the present invention, there is provided a method of forming the NMOS transistor. An insulation layer is formed on a semiconductor substrate. A first conductive layer comprising a metal-containing material is formed on the insulation layer, and a second conductive layer comprising metal and silicon is artificially formed on the first conductive layer by a CVD process, a silicidation process or a sputtering process. A third conductive layer comprising polysilicon is formed on the second conductive layer. The third, second and first conductive layers are sequentially patterned by a photolithography process, thereby forming a gate conductive pattern including a first conductive pattern, a second conductive pattern and a third conductive pattern sequentially stacked on the insulation layer. The insulation layer is patterned in such a way that the insulation layer remains under the gate conductive pattern, so that a gate insulation pattern is formed under the gate conductive pattern, to thereby form a gate pattern including the gate insulation pattern and the gate conductive pattern on the substrate. Source/drain regions are formed at surface portions of the substrate adjacent to the gate pattern by implanting n-type impurities onto the substrate.

According to an aspect of the present invention, there is provided a method of forming the PMOS transistor. An insulation layer is formed on a semiconductor substrate. A first conductive layer comprising a metal-containing material is formed on the insulation layer, and a second conductive layer comprising metal and silicon is artificially formed on the first conductive layer by a CVD process, a silicidation process or a sputtering process. A third conductive layer comprising polysilicon is formed on the second conductive layer. The third, second and first conductive layers are sequentially patterned by a photolithography process, thereby forming a gate conductive pattern including first, second and third conductive patterns sequentially stacked on the insulation layer. The insulation layer is patterned in such a way that the insulation layer remains under the gate conductive pattern, so that a gate insulation pattern is formed under the gate conductive pattern, to thereby form a gate pattern including the gate insulation pattern and the gate conductive pattern on the substrate. Source/drain regions are formed at surface portions of the substrate adjacent to the gate pattern by implanting p-type impurities onto the substrate.

According to an aspect of the present invention, there is provided a method of forming the CMOS transistor. An insulation layer is formed on a semiconductor substrate including a first area and a second area. A first conductive layer comprising a metal-containing material is formed on the insulation layer. A second conductive layer comprising metal and silicon is artificially formed on the first conductive layer. A third conductive layer comprising polysilicon is formed on the second conductive layer. The third, second and first conductive layers are sequentially patterned by a photolithography process, thereby forming a first gate conductive pattern including first, second and third conductive patterns sequentially stacked on the insulation layer in the first area of the substrate and a second gate conductive pattern including fourth, fifth and sixth conductive patterns sequentially stacked on the insulation layer in the second area of the substrate. The insulation layer is patterned in such a way that the insulation layer remains under the first and second gate conductive patterns, so that a first gate insulation pattern is formed under the first gate conductive pattern and a second gate insulation pattern is formed under the second gate conductive pattern, to thereby form a first gate pattern including the first gate insulation pattern and the first gate conductive pattern in the first area of the substrate and a second gate pattern including the second gate insulation pattern and the second gate conductive pattern in the second area of the substrate. First source/drain regions are formed at surface portions of the substrate adjacent to the first gate pattern by implanting n-type impurities onto the first area of the substrate, and second source/drain regions are formed at surface portions of the substrate adjacent to the second gate pattern by implanting p-type impurities onto the second area of the substrate.

According to the present invention, the gate structure includes a first layer comprising a metal-containing material, a second layer comprising a metal and silicon and a third layer comprising polysilicon. The second layer comprising metal and silicon is artificially and intentionally formed on the first layer comprising the metal-containing material, but is not natively formed at a boundary surface of the first and third layers due to a chemical reaction of the metal-containing material of the first layer and polysilicon of the third layer in a subsequent process. Particularly, the second layer artificially formed by a CVD process, a sputtering process or a silicidation process has superior electrical characteristics to those of a byproduct layer natively formed by the chemical reaction of the metal-containing material and polysilicon in a subsequent process, although both of the second layer and the byproduct layer comprise metal and silicon.

In this manner, the electrical characteristics of a gate structure may be sufficiently improved as compared with a conventional gate structure, thereby sufficiently improving the electrical characteristics of a transistor including the gate structure as a gate conductive pattern.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a cross-sectional view illustrating a gate structure for a semiconductor device according to an example embodiment of the present invention;

FIGS. 2A to 2C are cross-sectional views illustrating processing steps for a method of forming the gate structure shown in FIG. 1;

FIG. 3 is a cross-sectional view illustrating an n-type metal-oxide semiconductor (NMOS) transistor according to an example embodiment of the present invention;

FIGS. 4A to 4D are cross-sectional views illustrating processing steps for a method of manufacturing the NMOS transistor shown in FIG. 3;

FIG. 5 is a cross-sectional view illustrating a p-type MOS (PMOS) transistor according to an example embodiment of the present invention;

FIG. 6 is a cross-sectional view illustrating a complementary MOS (CMOS) transistor according to an example embodiment of the present invention; and

FIGS. 7A to 7D are cross-sectional views illustrating processing steps for a method of manufacturing the CMOS transistor shown in FIG. 6.

### DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than an abrupt change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Gate Structure and Method of Forming The Same

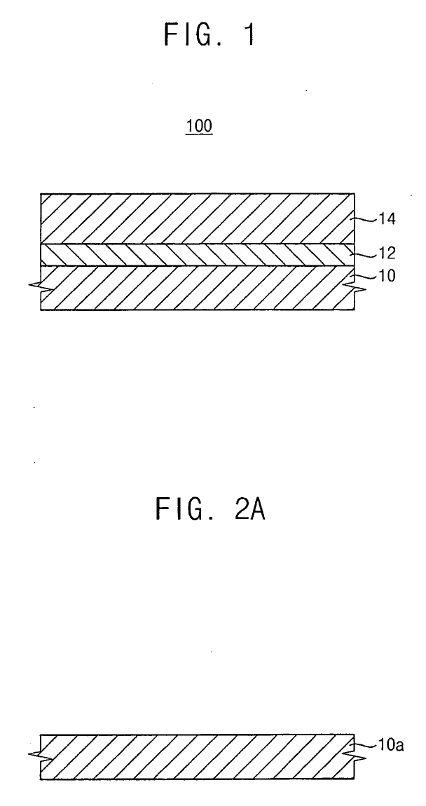

FIG. 1 is a cross-sectional view illustrating a gate structure for a semiconductor device according to an example embodiment of the present invention.

Referring to FIG. 1, a gate structure 100 of the present embodiment exemplarily functions as a gate conductive layer in a semiconductor device and includes first, second and third conductive patterns 10, 12 and 14.

The first conductive pattern 10 comprises a metal-containing material. The metal-containing material includes pure metal and a metal nitride. Examples of pure metal include nickel (Ni), tungsten (W), platinum (Pt), titanium (Ti), tantalum (Ta), zirconium (Zr), copper (Cu), ruthenium (Ru), hafnium (Hf), aluminum (Al) and iridium (Ir). Examples of the metal nitride include tungsten nitride, titanium nitride, titanium aluminum nitride, hafnium nitride, hafnium aluminum nitride, tantalum nitride, tantalum aluminum nitride, zirconium nitride, zirconium aluminum nitride and aluminum nitride. These can be used alone or in combinations thereof.

The first conductive pattern 10 may be formed by a chemical vapor deposition (CVD) process, a sputtering process or an atomic layer deposition (ALD) process. When the gate structure 100 is applied to a transistor of the semiconductor device having a design rule of about 60 nm to about 120 nm, the first conductive pattern 10 may be formed to a thickness of about 30 Å to about 120 Å. For example, the first conductive pattern 10 is formed to a thickness of about 60 Å to about 150 Å, and more particularly, to a thickness of about 80 Å to about 120 Å. In the present embodiment, the first conductive pattern 10 is formed to a thickness of about 100 Å.

The second conductive pattern 12 is formed on the first conductive pattern 10 and comprises metal and silicon. In the present embodiment, metal in the second conductive pattern 12 is substantially the same as in the first conductive pattern 10. Therefore, when the first conductive pattern 10 comprises tungsten or tungsten nitride, the second conductive pattern 12 comprises tungsten, and when the first conductive pattern 10 comprises titanium aluminum nitride, the second conductive pattern 12 comprises titanium aluminum.

In the present embodiment, the second conductive layer 12 is artificially and intentionally formed on the first conductive pattern 10 by a chemical vapor deposition (CVD) process, a sputtering process or a silicidation process, but is not natively or spontaneously formed at a boundary surface of the first and third conductive patterns 10 and 14 due to a chemical reaction of the metal-containing material in the first conductive pattern 10 and polysilicon in the third conductive pattern 14. Hereinafter, the word ‘artificial’ or ‘intentional’ means ‘not native’ or ‘not spontaneous’ due to a chemical reaction of contact materials. An intentional performance of one of the CVD process, the sputtering process and the silicidation process using metal and silicon on the first conductive pattern 10 causes a formation of the second conductive pattern 12 including a metal silicide thin layer therein. When the gate structure 100 is applied to a transistor of the semiconductor device having a design rule of about 60 nm to about 120 nm, the second conductive pattern 12 may be formed artificially to a thickness of about 20 Å to about 100 Å. For example, the second conductive pattern 12 is formed to a thickness of about 30 Å to about 80 Å, and more particularly, to a thickness of about 40 Å to about 60 Å. In the present embodiment, the second conductive pattern 12 is formed to a thickness of about 50 Å.

Further, the second conductive pattern 12 is artificially or intentionally formed on the first conductive pattern 10 by one of the CVD process, the sputtering process and the silicidation process, so that a layer structure of the second conductive pattern 12 is more stable than that of a byproduct layer that comprises byproducts resulting from a chemical reaction of metal and polysilicon in a subsequent process. Accordingly, the second conductive pattern 12 has superior electrical characteristics to those of the byproduct layer.

When the second conductive layer 12 of the gate structure 100 is exposed to an external environment, a surface of the second conductive layer 12 tends to be easily oxidized and an external stress may be directly applied onto the second conductive layer 12. For the above reasons, the third conductive layer pattern 14 is formed on the second conductive pattern 12. In the present embodiment, the third conductive pattern 14 comprises polysilicon, because polysilicon is favorable to high integration and has high thermal reliability. In addition, the second conductive pattern 12 is interposed between the first and third conductive patterns 10 and 14 and the third conductive pattern 14 is prevented from making direct contact with the first conductive pattern 10, so that polysilicon in the third conductive pattern 14 is sufficiently prevented from being chemically reacted with the metal in the first conductive pattern 10 in advance.

In the present embodiment, the third conductive pattern 14 is formed by a CVD process. When the gate structure 100 is applied to a transistor of the semiconductor device having a design rule of about 60 nm to about 120 nm, the third conductive pattern 14 may be formed to a thickness of about 500 Å to about 1,500 Å. For example, the third conductive pattern 14 is formed to a thickness of about 800 Å to about 1,200 Å, and more particularly, to a thickness of about 850 Å to about 1,150 Å. In the present embodiment, the third conductive pattern 14 is formed. to a thickness of about 950 Å. As an example embodiment, impurities may be introduced into the third conductive pattern 14. The third conductive pattern 14 may comprise polysilicon doped with the impurities, or the impurities may be implanted onto a polysilicon layer in a subsequent process, to thereby complete the third conductive pattern 14.

While the above example embodiment discloses each thickness of the first, second and third conductive patterns 10, 12 and 14 as numerical ranges, each thickness of the patterns 10, 12 and 14 may be represented as a ratio between the first, second and third conductive patterns 10, 12 and 14, as would be known to one of ordinary skill in the art. For example, the first conductive pattern 10 may be about 0.3 times to about 10.0 times as thick as the second conductive pattern 12, and the third conductive pattern 14 may be about 8.0 times to about 75.0 times as thick as the second conductive pattern 12.

Accordingly, the gate structure 100 includes the first conductive pattern 10 comprising a metal-containing material, the second conductive pattern 12 intentionally formed on the first conductive pattern 10 and comprising metal and silicon, and the third conductive pattern 14 comprising polysilicon.

Therefore, the gate structure 100 of the present embodiment may have the above advantages of the metal-containing material. In addition, the third conductive pattern 14 may mitigate the effect of the external stress on the first conductive layer 10 and prevent the oxidation of the first conductive pattern 10. Particularly, the gate structure 100 includes the second conductive pattern 12 interposed between the first and third conductive patterns 10 and 14. The second conductive pattern 12 is formed on the first conductive pattern 10 to a sufficient thickness to prevent a chemical reaction of metal in the first conductive pattern 10 and polysilicon in the third conductive pattern 14, to thereby improve electrical reliability of the gate structure 100. That is, no byproducts are produced on a boundary surface of the first and third conductive patterns 10 and 14 in the gate structure 100.

Hereinafter, a method of forming the above gate structure is described in detail.

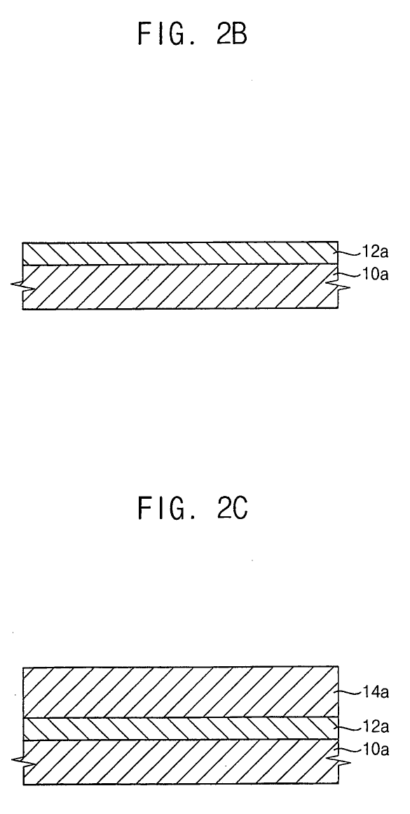

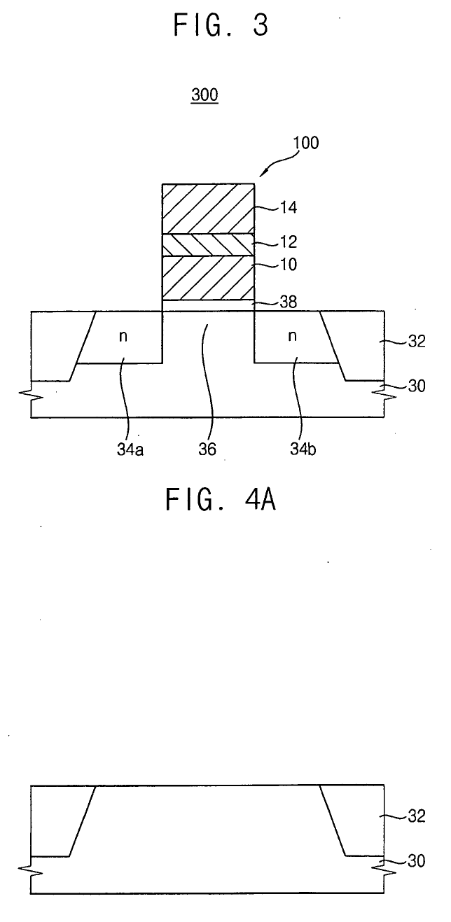

FIGS. 2A to 2C are cross-sectional views illustrating processing steps for a method of forming the gate structure shown in FIG. 1.

Referring to FIG. 2A, a first conductive layer 10a is formed on a substrate (not shown) by a CVD process, a sputtering process or an ALD process using a metal-containing material. The first conductive layer 10a is to be formed into the first conductive pattern 10 of the gate structure 100 in a subsequent process, so that the first conductive layer 10a comprises the metal-containing material such as pure metal and metal nitride and is formed to a thickness of about 30 Å to about 200 Å.

Referring to FIG. 2B, a second conductive layer 12a is formed on the first conductive layer 10a by a CVD process, a sputtering process or a silicidation process. The second conductive layer 12a is to be formed into the second conductive pattern 12 of the gate structure 100 in a subsequent process, so that the second conductive layer 12a comprises metal and silicon and is formed to a thickness of about 20 Å to about 100 Å. As an example embodiment, the metal in the second conductive layer 12a is substantially the same as that in the first conductive layer 10a. For example, when the first conductive layer 10a comprises tungsten or tungsten nitride, the second conductive layer 12a comprises tungsten silicide.

Referring to FIG. 2C, a third conductive layer 14a is formed on the second conductive layer 12a by a CVD process. The third conductive layer 14a is to be formed into the third conductive pattern 14 of the gate structure 100 (see FIG. 3) in a subsequent process, so that the third conductive layer 14a comprises polysilicon and is formed to a thickness of about 500 Å to about 1,500 Å.

Then, the first, second and third conductive layers 10a, 12a and 14a are sequentially patterned by a photolithography process using a photoresist pattern as an etching mask, thereby forming a gate structure 100 including the first, second and third conductive patterns 10, 12 and 14.

N-Type Metal-Oxide Semiconductor (NMOS) Transistor and Method of Manufacturing the Same

FIG. 3 is a cross-sectional view illustrating an NMOS transistor according to an example embodiment of the present invention. In FIG. 3, the same reference numerals denote the same elements in FIG. 1.

Referring to FIG. 3, a unit cell of an NMOS transistor 300 of the present embodiment includes a semiconductor substrate 30 and a gate pattern on the substrate 30. The gate pattern includes a gate insulation pattern 38 and a gate conductive pattern. In the present embodiment, the gate conductive pattern includes the gate structure 100 shown in FIG. 1. The semiconductor substrate 30 includes a silicon substrate, a silicon-on-insulator (SOI) substrate, a germanium substrate, a germanium-on-insulator (GOI) substrate and a silicon germanium substrate. In the present embodiment, the substrate 30 includes the silicon substrate. Because the NMOS transistor 300 is formed on the substrate 30, the substrate 30 includes a p-type well (not shown) at surface portions thereof into which p-type dopants are lightly implanted.

The substrate 30 includes an active region and a field region enclosing the active region and an insulation layer 32 is formed in the field region, so that the active region is electrically isolated from an adjacent active region by the insulation layer 32 in the field region. The gate pattern is formed on the active region of the substrate 30, and neighboring gate patterns adjacent to each other are electrically isolated from each other by the insulation layer 32. For that reason, the insulation layer 32 is referred to as a device isolation layer hereinafter. The device isolation layer 32 includes a field oxide layer and a trench isolation layer. In the present embodiment, the trench isolation layer is utilized as the device isolation layer because the trench isolation layer is more favorable to high integration than the field oxide layer.

The NMOS transistor 300 utilizes free electrons as a charge carrier, so that source/drain regions 34a and 34b doped with n-type impurities are formed at surface portions of the substrate 30 for generation of the free electrons. Particularly, the source/drain regions 34a and 34b are formed at the surface portions of the substrate adjacent to the gate pattern. Examples of the n-type impurities include phosphorus (P), arsenic (As), etc. These can be used alone or in combinations thereof. An ion implantation process may be performed for doping the n-type impurities into the source/drain regions 34a and 34b.

When the source/drain regions 34a and 34b are formed at surface portions of the substrate 30, a channel region 36 is positioned between the source/drain regions 34a and 34b.

Therefore, the gate pattern including the gate insulation pattern 38 and the gate structure 100 is positioned on the channel region 36 of the substrate 30. The gate insulation pattern 38 is interposed between the gate structure 100 and the channel region 36, so that current leakage is not generated between the gate structure 100 functioning as a gate conductive pattern and the channel region 36. That is, the gate structure 100 is electrically insulated from the channel region 36 by the gate insulation layer 38.

The gate insulation layer 38 comprises an insulation material. Examples of the insulation material include silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride, etc. These can be used alone or in combinations thereof. In the present embodiment, the gate insulation pattern 38 comprises the above-mentioned metal oxide because the current leakage is sufficiently reduced between the gate structure 100 and the channel region 36 at a sufficiently small equivalent oxide thickness (EOT).

The NMOS transistor 300 includes the gate structure 100 shown in FIG. 1 on the gate insulation pattern 38 as the gate conductive pattern. The gate structure 100 is hereinafter referred to as gate conductive pattern. Accordingly, the gate conductive pattern 100 includes first, second and third conductive patterns 10, 12 and 14.

The first conductive pattern 10 comprises metal-containing material such as pure metal and metal nitride, and is formed to a thickness of about 30 Å to about 120 Å. The second conductive pattern 12 comprises metal and silicon, and is formed to a thickness of about 20 Å to about 100 Å. The third conductive pattern 14 comprises polysilicon, and is formed to a thickness of about 500 Å to about 1,500 Å.

Particularly, the gate insulation pattern 38 comprises a metal oxide without any difficulty because the first conductive pattern 10 comprises a metal-containing material. In the present embodiment, the metal-containing material of the first conductive pattern 10 may have a work function of about 4.0 eV. The second conductive pattern 12 comprises substantially the same metal as in the first conductive pattern 10 and is formed to a predetermined thickness on the first conductive pattern 10 by a CVD process, a sputtering process or a silicidation process. Therefore, the gate conductive pattern 100 includes a metal-containing material in the first conductive pattern 10 and polysilicon in the third conductive pattern 14.

Accordingly, the NMOS transistor 300 includes the gate insulation pattern 38 comprising a metal oxide and the gate conductive pattern 100 comprising the metal-containing material and polysilicon, so that the NMOS transistor 300 may be manufactured at a high integration degree with improved electrical characteristics. That is, the NMOS transistor 300 has a small EOT and a small leakage current due to the metal oxide of the gate insulation pattern 38, a controlled and stable threshold voltage and improved resistance characteristics due to the metal-containing material, and a high integration degree and improved electrical reliability due to polysilicon. As a result, the NMOS transistor 300 of the present embodiment has remarkably improved electrical characteristics.

Hereinafter, a method of manufacturing the above NMOS transistor is described in detail.

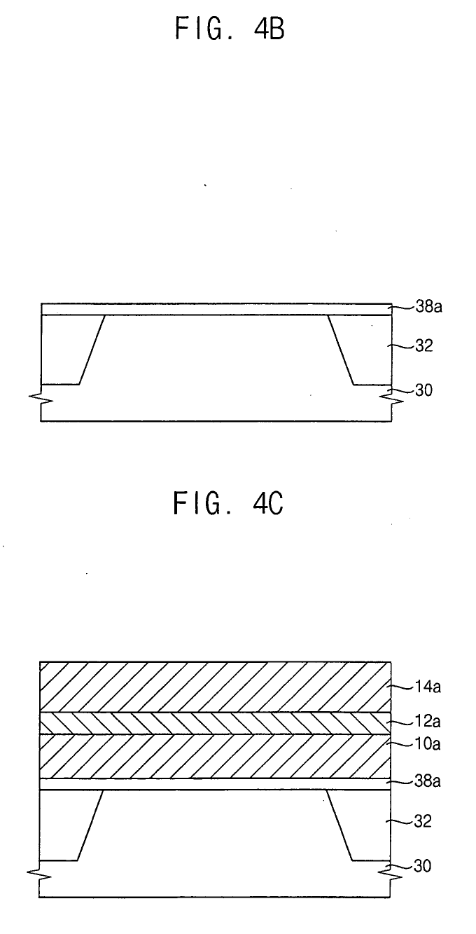

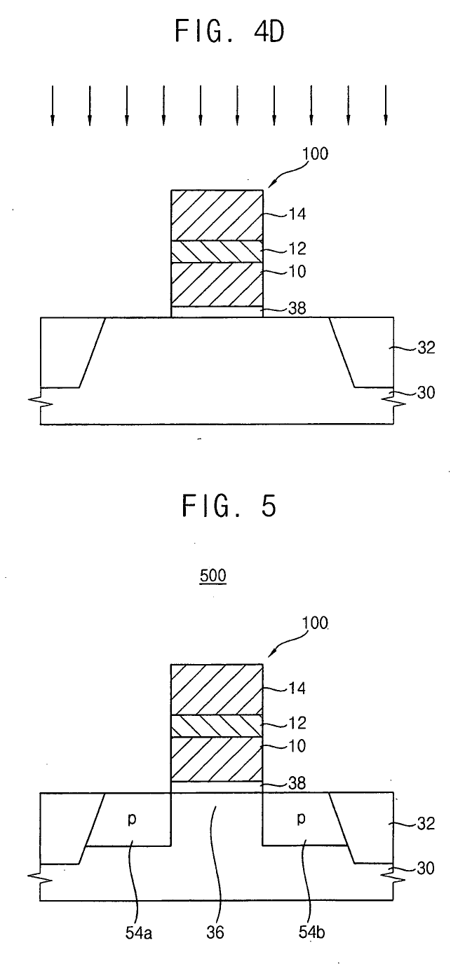

FIGS. 4A to 4D are cross-sectional views illustrating processing steps for a method of manufacturing the NMOS transistor shown in FIG. 3.

Referring to FIG. 4A, a trench isolation layer is formed on the substrate 30 as a device isolation layer 32, and an active region is defined by the field region on the substrate 30. The trench isolation layer is used as the device isolation layer in the present embodiment in view of an integration degree of the NMOS transistor.

A pad oxide layer and a pad nitride layer are formed on the substrate 30, and are sequentially patterned by a photolithography process, to thereby form a pad oxide pattern and a pad nitride pattern on the substrate 30. A surface of the substrate 30 is partially exposed through the pad oxide pattern and the pad nitride pattern. The substrate 30 is partially etched off using the pad oxide pattern and the pad nitride pattern as an etching mask, thereby forming a trench on the substrate 30. A curing process may be further performed on the substrate 30 so as to cure damage to the substrate 30 in the above etching process for a formation of the trench. An oxide thin layer having superior gap-fill characteristics is then formed on the substrate 30 to a sufficient thickness to fill up the trench. In the present embodiment, the oxide thin layer may be formed by a plasma-enhanced CVD (PECVD) process. Then, the oxide thin layer is removed from the substrate 30 by a planarization process such as a chemical mechanical polishing (CMP) process until a top surface of the pad nitride pattern is exposed, so that the oxide thin layer only remains in the trench. Thereafter, the pad oxide pattern and the pad nitride pattern are removed from the substrate 30 by an etching process using, for example, phosphoric acid. As a result, the trench of the substrate 30 is sufficiently filled up with the oxide thin layer, to thereby form the trench isolation layer as the device isolation layer 32.

Referring to FIG. 4B, an insulation layer 38a is formed on the substrate 30 including the device isolation layer 32. The insulation layer 38a is formed into the gate insulation pattern 38 in a subsequent process, so that the insulation layer 38a comprises a metal oxide and is formed to an EOT of about 20 Å. In the present embodiment, the insulation layer 38a may be formed on the substrate 30 by an ALD process, because metal oxide is included in the insulation layer 38a.

As an example embodiment, the ALD process used for formation of the metal oxide layer as the insulation layer is performed as follows: The process chamber is set to be a temperature of about 200° C. to about 500° C. and a pressure of about 0.3 Torr to about 3.0 Torr. The substrate 30 is positioned in the process chamber and a reactant including a metal precursor is supplied onto the substrate 30 for a time of about 0.5 s to about 3 s. A first portion of the reactant is chemisorbed on the substrate 30, and a second portion of the reactant, which is a remaining portion of the reactant except for the first portion, is physisorbed on the first portion of the reactant or drift in the processing chamber. A purge gas such as an argon gas is supplied into the processing chamber for a time of about 0.5 s to about 20 s. The second portion of the reactant that is physisorbed on the first portion or drift in the processing chamber is removed from the chamber by the purge gas, so that only the first portion of the reactant is chemisorbed on the substrate 30. That is, only the metal precursor molecules remain on the substrate 30. Thereafter, an oxidizing agent is provided into the chamber for a time of about one second to about seven seconds, and is chemically reacted with the metal precursor molecules on the substrate 30. Accordingly, the metal precursor molecules are oxidized in the processing chamber. Then, the purge gas is again provided into the processing chamber, so that a residual oxidizing agent, which is not chemically reacted with the metal precursor molecules, is removed from the chamber by the purge gas, thereby completing a cycle of the ALD process. As a result, a solid material including the metal oxide is produced on a surface of the substrate 30. A repetition of the above cycle of the ALD process forms the insulation layer 38a on the substrate 30 to a desired thickness.

Referring to FIG. 4C, first, second and third conductive layers 10a, 12a and 14a are sequentially formed on the insulation layer 38a. In the present embodiment, the first, second and third conductive layers 10a, 12a and 14a are substantially the same as the first, second and third conductive layers as described with reference to FIGS. 2A to 2C. Accordingly, the first conductive layer 10a is formed on the insulation layer 38a to a thickness of about 30 Å to about 200 Å by a CVD process, an ALD process and a sputtering process. The second conductive layer 12a is formed on the first conductive layer 10a to a thickness of about 20 Å to about 100 Å by a CVD process, a sputtering process and a silicidation process. The third conductive layer 14a comprising polysilicon is formed on the second conductive layer 12a to a thickness of about 500 Å to about 1,500 Å by a CVD process.

Referring to FIG. 4D, the third, second and first conductive layers 14a, 12a and 10a are sequentially removed from the insulation layer 38a by a photolithography process using a photoresist pattern (not shown) as an etching mask, thereby forming a first conductive pattern 10, a second conductive pattern 12 and a third conductive pattern 14 on the insulation layer 38a. The first, second and third conductive patterns 10, 12 and 14 completes a gate conductive pattern 100 of the NMOS transistor 300 in FIG. 3. Then, the insulation layer 38a is patterned by a photolithography process using the gate conductive pattern 100 as an etching mask, thereby forming a gate insulation pattern 38. Accordingly, a gate pattern including the gate insulation pattern 38 and the gate conductive pattern 100 is formed on the substrate 30.

Then, a first ion implantation process is performed on the substrate 30 using the gate pattern as an ion implantation mask. In the present embodiment, n-type impurities are lightly implanted onto the substrate 30. Examples of the n-type impurities include phosphorus (P), arsenic (As), etc.

As a result, the source/drain regions 34a and 34b in FIG. 3 lightly doped with the n-type impurities are formed at surface portions of the substrate 30 adjacent to the gate pattern, thereby completing the NMOS transistor 300 shown in FIG. 3. Although the third conductive pattern 14 comprises pure polysilicon that is not doped with impurities, substantially the same impurities as implanted onto the substrate 30 in the process for a formation of the source/drain regions 34a and 34b may also be implanted onto the third conductive pattern 14a, thereby sufficiently improving electrical reliability of the third conductive pattern 14.

As an example embodiment of the present invention, a gate spacer (not shown) may be further formed on a side surface of the gate pattern after a formation of the source/drain regions 34a and 34b. The gate spacer may comprise silicon nitride, and a sequential process of deposition and etching processes may be performed on the substrate including the gate pattern for a formation of the gate spacer. Then, the n-type impurities are heavily implanted onto the substrate 30 by a second ion implantation process using the gate pattern and the gate spacer as an ion implantation mask. While n-type impurities are lightly doped into the substrate 30 during the first ion implantation process, to thereby form a shallow junction region on the substrate 30, the n-type impurities are heavily doped into the substrate 30 during the second ion implantation process, to thereby form a deep junction region on the substrate 30. Accordingly, the source/drain regions 34a and 34b may be formed into a lightly doped source/drain (LDD) structure including the shallow junction region and a deep junction region by the sequential performance of the first and second ion implantation processes.

P-type MOS (PMOS) Transistor and Method of Manufacturing the Same

FIG. 5 is a cross-sectional view illustrating a PMOS transistor according to an example embodiment of the present invention. In FIG. 5, the same reference numerals denote the same elements in FIG. 1.

Referring to FIG. 5, a PMOS transistor 500 of the present embodiment is substantially the same structure as the NMOS transistor 300 shown in FIG. 3 except for the impurities used in formation of the source/drain regions.

A unit cell of the PMOS transistor 500 includes a semiconductor substrate 30 and a gate pattern on the substrate 30. The gate pattern includes a gate insulation pattern 38 and a gate conductive pattern. In the present embodiment, the gate conductive pattern includes the gate structure 100 shown in FIG. 1.

The semiconductor substrate 30 also includes an active region and a field region enclosing the active region and an insulation layer 32 is formed in the field region, so that the active region is electrically isolated from an adjacent active region by the insulation layer 32 in the field region. The gate pattern is formed on the active region of the substrate 30, and neighboring gate patterns adjacent to each other are electrically isolated from each other by the insulation layer 32. For that reason, the insulation layer 32 is referred to as a device isolation layer hereinafter. A channel region 36 is also formed between source/drain regions 54a and 54b. Because the PMOS transistor 500 is formed on the substrate 30, the substrate 30 includes an n-type well (not shown) at surface portions thereof into which n-type dopants are lightly implanted.

The PMOS transistor 500 utilizes holes as a charge carrier, so that the source/drain regions 54a and 54b doped with p-type impurities are formed at surface portions of the substrate 30 for generation of the holes. Examples of the p-type impurities. include boron (B). An ion implantation process may be performed for doping the p-type impurities into the source/drain regions 54a and 54b. In the present embodiment, a first conductive pattern 10 of a gate structure comprises a metal-containing material having a work function of about 5.0 eV.

According to the PMOS transistor 500 of the present embodiment, the gate insulation pattern 38 also comprises metal oxide and the gate conductive pattern 100 also includes the gate structure comprising a metal-containing material and polysilicon. In addition, the gate conductive pattern 100 is also formed to a structure in which the second conductive pattern 12 comprising a metal and polysilicon is interposed between the first and third conductive patterns 10 and 14. Particularly, the second conductive pattern 12 is formed on the first conductive pattern 10 to a predetermined thickness by a CVD process or a silicidation process.

Therefore, the PMOS transistor 500 of the present embodiment has a small EOT and a small leakage current due to the metal oxide of the gate insulation pattern 38, a controlled and stable threshold voltage and improved resistance characteristics due to the metal-containing material, and a high integration degree and improved electrical reliability due to polysilicon. As a result, the PMOS transistor 500 of the present embodiment has remarkably improved electrical characteristics.

Furthermore, the second conductive pattern 12 is interposed between the first and third conductive patterns 10 and 14 in the PMOS transistor 500 and the third conductive pattern 14 is prevented from making direct contact with the first conductive pattern 10, so that polysilicon in the third conductive pattern 14 is sufficiently prevented from being chemically reacted with the metal in the first conductive pattern 10 in advance. As a result, byproducts of the chemical reaction of the first and third conductive patterns 10 and 14 are not generated at a boundary surface of the first and third conductive patterns 10 and 14, thereby sufficiently preventing a reduction of electrical reliability of the PMOS transistor 500.

Hereinafter, a method of manufacturing the above PMOS transistor is described in detail.

Substantially the same processing steps as described with reference to FIGS. 4A to 4C are performed on a semiconductor substrate, thereby manufacturing the above PMOS transistor 500 shown in FIG. 5.

A device isolation layer 32 is formed on the substrate 30, and an insulation layer 38a and first, second and third conductive layers 10a, 12a and 14a are sequentially formed on the substrate.

Then, substantially the same patterning process as described with reference to FIG. 4D is performed on the substrate including the insulation layer 38a and the conductive layers 10a, 12a and 14a, so that a gate insulation pattern 38 and a gate conductive pattern 100 are formed on the substrate. The gate conductive pattern 100 also includes a first conductive pattern 10, a second conductive pattern 12 and a third conductive pattern 14.

P-type impurities are implanted onto the substrate by an ion implantation process using the gate pattern as an ion implantation mask. Because the transistor of the present embodiment is a p-type, the impurities implanted onto the substrate are also a p-type. Examples of the p-type impurities include boron (B).

Implantation process as described above is performed to form source/drain regions 54a and 54b wherein the p-type impurities are doped under the surface portions of the semiconductor substrate 30, which are adjacent to the gate pattern. That is, performing the implantation process completes the PMOS transistor 500 as shown in FIG. 5.

As another example embodiment of the present invention, a gate spacer (not shown) may also be formed on a side surface of the gate pattern after the source/drain regions 54a and 54b doped with p-type impurities are formed at surface portions of the substrate, the source/drain regions 54a and 54b may also be formed into the LDD structure by an additional ion implantation process using the gate spacer as an ion implantation mask. P-type impurities are also implanted onto the substrate in the additional ion implantation process.

Complementary MOS (CMOS) Transistor and Method of Manufacturing the Same

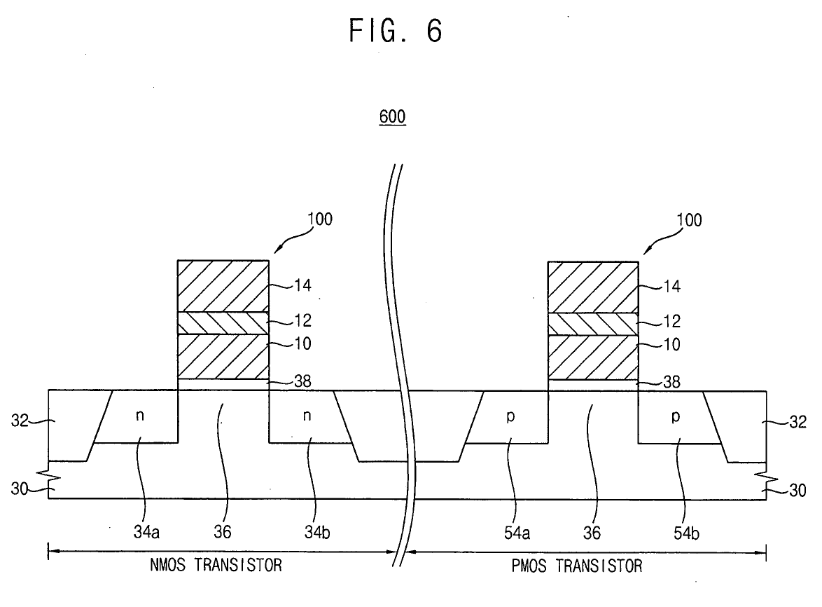

FIG. 6 is a cross-sectional view illustrating a CMOS transistor according to an example embodiment of the present invention. In FIG. 6, the same reference numerals denote the same elements in FIGS. 1, 3 and 5.

Referring to FIG. 6, a CMOS transistor 600 of the present embodiment includes the NMOS transistor 300 shown in FIG. 3 and the PMOS transistor shown in FIG. 5 that are formed on substantially the same substrate.

Accordingly, the CMOS transistor 600 includes an NMOS transistor and a PMOS transistor. The NMOS transistor includes an n-type source/drain regions 34a and 34b doped with n-type impurities and a gate pattern formed on a channel region 36 between the n-type source/drain regions 34a and 35a, and the PMOS transistor includes a p-type source/drain regions 54a and 54b doped with p-type impurities and a gate pattern formed on a channel region 36 between the p-type source/drain regions 54a and 54b.

Particularly, a p-type well doped with p-type impurities is partially formed at an upper portion of the substrate 30 on which the NMOS transistor is to be formed, and an n-type well doped with n-type impurities is partially formed at an upper portion of the substrate 30 on which the PMOS transistor is to be formed.

The gate insulation pattern 38 of the PMOS transistor and the NMOS transistor comprises an insulation material. Examples of the insulation material include silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride, etc. These can be used alone or in combinations thereof.

The gate conductive pattern 100 of the PMOS transistor and the NMOS transistor is substantially the same structure as the gate conductive pattern shown in FIG. 1. Accordingly, the gate conductive pattern 100 includes a first conductive pattern 10 comprising a metal-containing material, a second conductive pattern 12 comprising a metal-containing material and silicon and a third conductive pattern 14 comprising polysilicon. Particularly, the second conductive pattern 12 is formed on the first conductive pattern 10 to a predetermined thickness by a CVD process or a silicidation process. In the present embodiment, the first conductive pattern 10 of the NMOS transistor comprises a metal-containing material having a work function of about 4.0 eV, and the first conductive pattern 10 of the PMOS transistor comprises a metal-containing material having a work function of about 5.0 eV.

The NMOS transistor utilizes free electrons as a charge carrier, so that the n-type source/drain regions 34a and 34b, which are doped with n-type impurities, are formed at surface portions of the substrate 30 for generation of the free electrons. Examples of the n-type impurities include phosphorus (P) and arsenic (As). The PMOS transistor utilizes holes as a charge carrier, so that the p-type source/drain regions 54a and 54b, which are doped with p-type impurities, are formed at surface portions of the substrate 30 for generation of the holes. Examples of the p-type impurities include boron (B).

According to the CMOS transistor 600 of the present embodiment, the gate insulation pattern 38 comprises metal oxide, so that the CMOS transistor 600 of the present embodiment has a small EOT and a small leakage current due to the metal oxide of the gate insulation pattern 38. In addition, the gate conductive pattern 100 also includes the gate structure comprising a metal-containing material and polysilicon, so that the CMOS transistor 600 of the present embodiment has a controlled and stable threshold voltage and improved resistance characteristics due to the metal-containing material and a high integration degree and improved electrical reliability due to the presence of the polysilicon. As a result, the CMOS transistor 600 of the present embodiment has remarkably improved electrical characteristics.

Further, the gate conductive pattern 100 is also formed to a structure in which the second conductive pattern 12 comprising metal and silicon is interposed between the first and third conductive patterns 10 and 14 in the PMOS transistor and the NMOS transistor of the CMOS transistor 600, so that the third conductive pattern 14 is prevented from making direct contact with the first conductive pattern 10 and polysilicon in the third conductive pattern 14 is sufficiently prevented from being chemically reacted with the metal in the first conductive pattern 10 in advance. As a result, byproducts of the chemical reaction of the first and third conductive patterns 10 and 14 are not generated at a boundary surface of the first and third conductive patterns 10 and 14, thereby sufficiently preventing a reduction of electrical reliability of the CMOS transistor 600.

Hereinafter, a method of manufacturing the above CMOS transistor is described in detail.

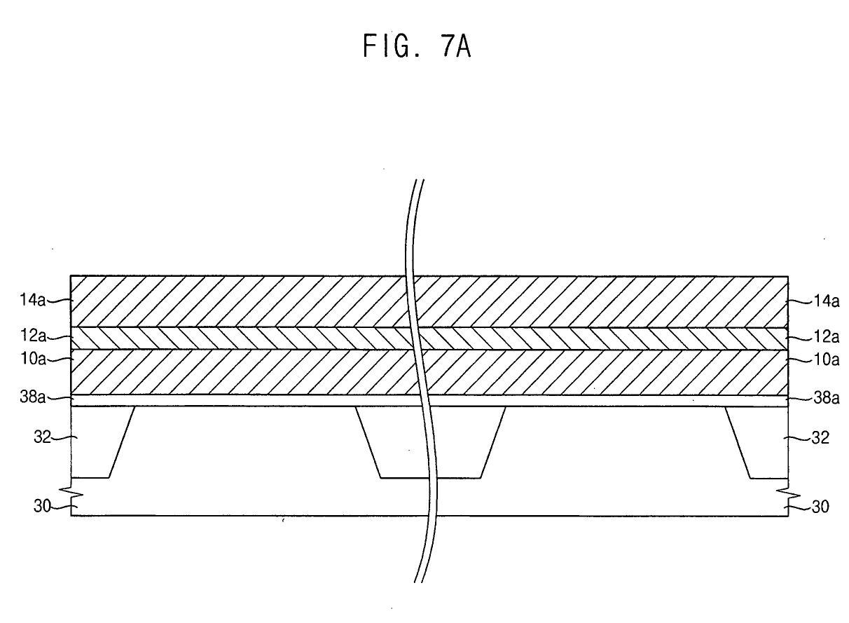

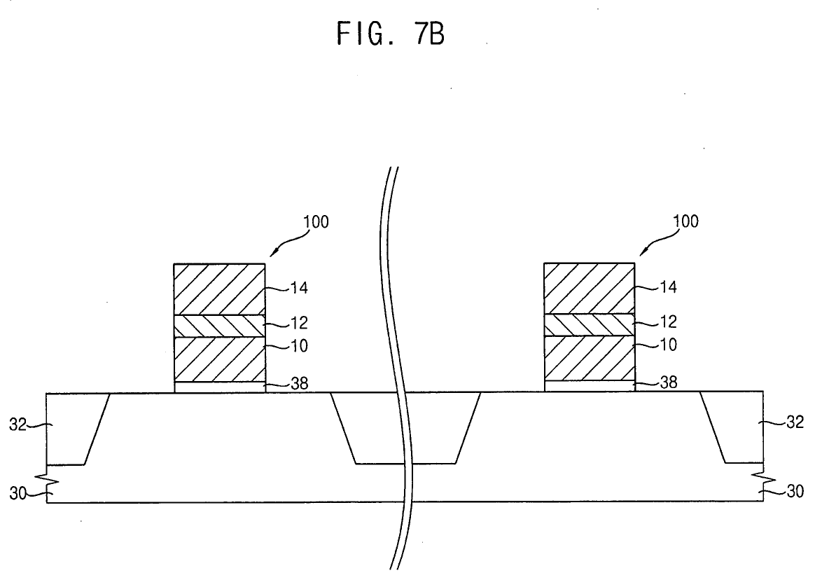

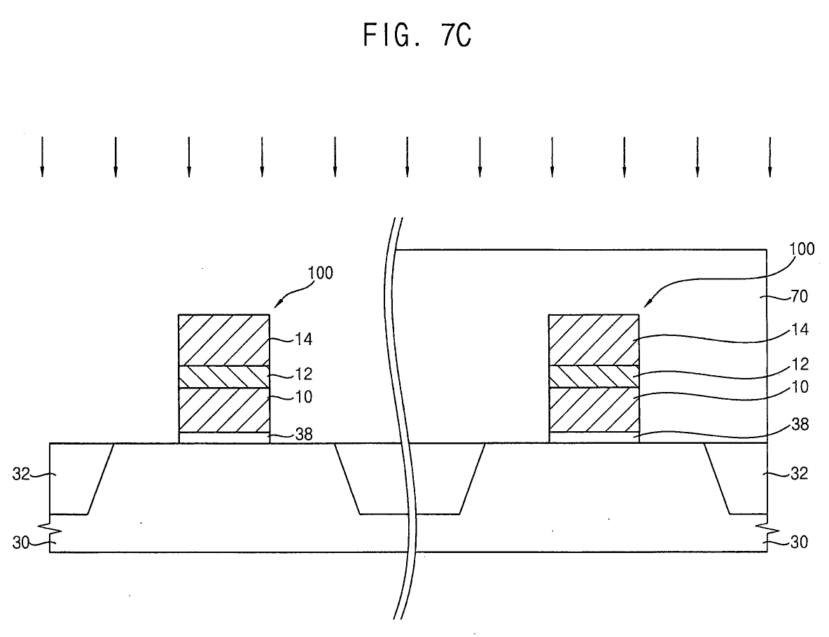

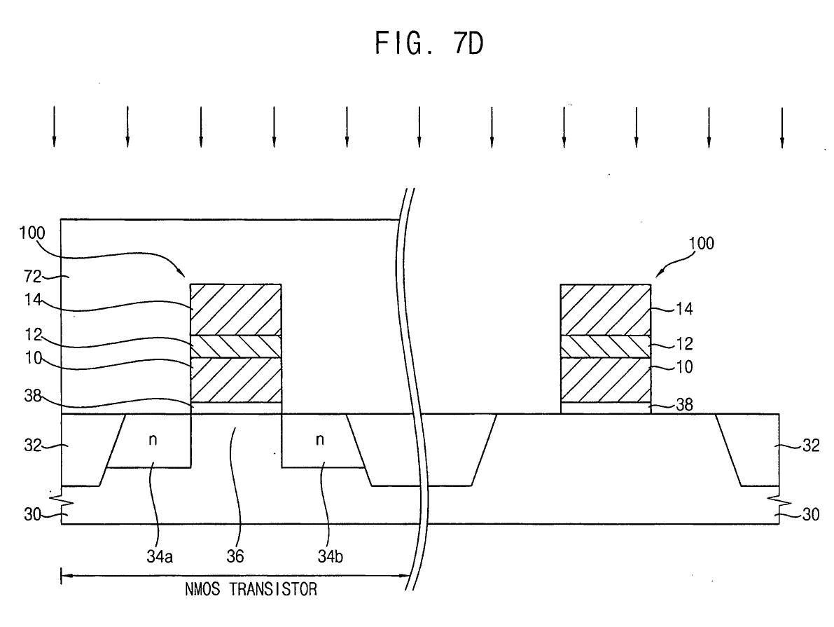

FIGS. 7A to 7D are cross-sectional views illustrating processing steps for a method of manufacturing the CMOS transistor shown in FIG. 6.

Referring to FIG. 7A, p-type impurities are lightly implanted onto a first portion of a semiconductor substrate 30 on which the NMOS transistor is to be formed, to thereby form a p-type well (not shown) on the substrate 30, and n-type impurities are lightly implanted onto a second portion of the semiconductor substrate 30 on which the PMOS transistor is to be formed, to thereby form an n-type well (not shown) on the substrate 30.

Then, substantially the same processing steps as described with reference to FIGS. 4A to 4C are performed on the substrate 30, so that a device isolation layer 32 is formed on the substrate 30, and an insulation layer 38a and first, second and third conductive layers 10a, 12a and 14a are sequentially formed on the substrate 30.

Referring to FIG. 7B, substantially the same patterning process as described with reference to FIG. 4D is performed on the substrate including the insulation layer 38a and the conductive layers 10a, 12a and 14a, so that a gate insulation pattern 38 and a gate conductive pattern 100 are formed on the substrate 30.

Hereinafter, the gate pattern for the NMOS transistor is referred to as first gate pattern and the gate pattern for the PMOS transistor is referred to as second gate pattern. In addition, the gate insulation pattern 38 for the first gate pattern is referred to as a first gate insulation pattern, and the gate conductive pattern 100 for the first gate pattern is referred to as a first gate conductive pattern. The gate insulation pattern 38 for the second gate pattern is referred to as a second gate insulation pattern, and the gate conductive pattern 100 for the second gate pattern is referred to as a second gate conductive pattern. Further, the first, second and third conductive patterns 10, 12 and 14 in the second conductive pattern 100 are referred to as fourth, fifth and sixth conductive patterns, respectively.

Referring to FIG. 7C, a first photoresist pattern 70 is formed on the substrate 30 by a photolithography process in such a structure that the first portion of the substrate 30 on which the NMOS transistor is to be formed is exposed and the second portion of the substrate 30 on which the PMOS transistor is to be formed is covered with the first photoresist pattern 70. Then, n-type impurities are implanted onto the substrate 30 by a first ion implantation process using the first gate pattern and the first photoresist pattern 70 as an ion implantation mask.

Accordingly, source/drain regions 34a and 34b doped with the n-type impurities are formed at surface portions of the substrate 30 adjacent to the first gate pattern, to thereby form the NMOS transistor on the substrate 30 by the first ion implantation process. Hereinafter, the source/drain regions 34a and 34b doped with the n-type impurities are referred to as first source/drain regions.

Thereafter, the first photoresist pattern 70 is removed from the substrate 30 by a stripping process.

As a modified example embodiment, a first gate spacer (not shown) may be further formed on a side surface of the first gate pattern after the first source/drain regions 34a and 34b are formed at the surface portions of the substrate 30, and another ion implantation process may be further performed on the substrate 30 using the first gate spacer as an ion implantation mask, to thereby form the first source/drain regions 34a and 34b into an LDD structure.

Referring to FIG. 7D, a second photoresist pattern 72 is formed on the substrate 30 by a photolithography process in such a structure that the first portion of the substrate 30 on which the NMOS transistor is to be formed is covered with the second photoresist pattern 72 and the second portion of the substrate 30 on which the PMOS transistor is to be formed is exposed. Then, p-type impurities are implanted onto the substrate 30 by a second ion implantation process using the second gate pattern and the second photoresist pattern 72 as an ion implantation mask.

Accordingly, source/drain regions 54a and 54b (see FIG. 6) doped with the p-type impurities are formed at surface portions of the substrate 30 adjacent to the second gate pattern, to thereby form the PMOS transistor on the substrate 30 by the second ion implantation process. Hereinafter, the source/drain regions 54a and 54b doped with the p-type impurities are referred to as second source/drain regions.

Thereafter, the second photoresist pattern 72 is removed from the substrate 30 by a stripping process.

As a modified example embodiment, a second gate spacer (not shown) may be further formed on a side surface of the second gate pattern after the second source/drain regions 54a and 54b are formed at the surface portions of the substrate 30, and another ion implantation process may be further performed on the substrate 30 using the second gate spacer as an ion implantation mask, to thereby form the second source/drain regions 54a and 54b into an LDD structure.

While the present example embodiment discloses that the first ion implantation process for implanting the n-type impurities for the NMOS transistor is performed prior to the second ion implantation process for implanting the p-type impurities for the PMOS transistor, the second ion implantation process may be performed prior to the first ion implantation process so that the PMOS transistor may be formed on the substrate prior to the NMOS transistor, as would be known to one of ordinary skill in the art.

According to the present invention, the gate conductive pattern of a gate structure comprises a metal-containing material, so that metal oxide may be easily used for the gate insulation pattern of the gate structure. Therefore, the gate structure has a small EOT and a small leakage current due to the presence of the metal oxide material in the gate insulation pattern. In addition, the gate structure includes a metal-containing material layer and a polysilicon layer on the metal-containing material layer, so that the gate structure has a controlled and stable threshold voltage and improved resistance characteristics due to the metal-containing material and a high integration degree and improved electrical reliability due to polysilicon. Further, the polysilicon layer mitigates the effect of the external stress on the metal-containing material layer and prevents oxidation of the metal-containing material layer.

Particularly, the gate structure includes an intermediate layer interposed between the metal-containing material layer and the polysilicon layer. The intermediate layer is formed on the metal-containing material layer to a sufficient thickness to prevent a chemical reaction of metal in the metal-containing material layer and polysilicon in the polysilicon layer on the metal-containing material layer. Accordingly, no byproducts are produced on a boundary surface of the metal-containing material layer and the polysilicon layer in the gate structure, to thereby improve electrical reliability of the gate structure.

As a result, the electrical reliability of NMOS and PMOS transistors including the gate structure is remarkably improved, and the electrical reliability of the CMOS transistor including the NMOS and PMOS transistors is also remarkably improved according to the present invention.

Although the example embodiments of the present invention have been described, it is understood that the present invention should not be limited to these example embodiments but various changes and modifications can be made by one skilled in the art within the spirit and scope of the present invention as hereinafter claimed.

What is claimed is:

1. A gate structure comprising:
a first conductive pattern comprising a metal-containing material;
a second conductive pattern on the first conductive pattern, the second conductive pattern comprising metal and silicon; and
a third conductive pattern on the second conductive pattern, the third conductive pattern comprising polysilicon.

2. The gate structure of claim 1, wherein a metal in the first conductive pattern is substantially identical to the metal in the second conductive pattern.

3. The gate structure of claim 1, wherein the second conductive pattern includes a metal silicide thin layer formed by one of a chemical vapor deposition (CVD) process, a sputtering process and a silicidation process.

4. The gate structure of claim 1, wherein a thickness of the first conductive pattern is about 0.3 to about 10 times a thickness of the second conductive pattern, and a thickness of the third conductive pattern is about 8.0 to about 75.0 times the thickness of the second conductive pattern.

5. The gate structure of claim 1, wherein the first conductive pattern has a thickness of about 30 Å to about 200 Å, the second conductive pattern has a thickness of about 20 Å to about 100 Å, and the third conductive pattern has a thickness of about 500 Å to about 1,500 Å.

6. The gate structure of claim 1, wherein the metal-containing material of the first conductive pattern includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

7. An n-type metal-oxide semiconductor (NMOS) transistor comprising:
a semiconductor substrate;
source/drain regions doped with n-type impurities at a first surface portion of the substrate;
a channel region at a second surface portion of the substrate between the source/drain regions; and
a gate pattern on the channel region, the gate pattern including a gate insulation pattern and a gate conductive pattern,
wherein the gate conductive pattern includes a first conductive pattern comprising a metal-containing material, a second conductive pattern comprising metal and silicon on the first conductive pattern, and a third conductive pattern comprising polysilicon on the second conductive pattern.

8. The NMOS transistor of claim 7, wherein a metal in the first conductive pattern is substantially identical to the metal in the second conductive pattern.

9. The NMOS transistor of claim 7, wherein the second conductive pattern includes a metal silicide thin layer formed by one of a CVD process, a sputtering process and a silicidation process.

10. The NMOS transistor of claim 7, wherein the first conductive pattern has a thickness of about 30 Å to about 200 Å, the second conductive pattern has a thickness of about 20 Å to about 100 Å, and the third conductive pattern has a thickness of about 500 Å to about 1,500 Å.

11. The NMOS transistor of claim 7, wherein the metal-containing material of the first conductive pattern includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

12. The NMOS transistor of claim 7, wherein the n-type impurities include any one selected from the group consisting of phosphorus (P), arsenic (As) and a combination thereof.

13. The NMOS transistor of claim 7, wherein the gate insulation pattern comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof.

14. A p-type MOS (PMOS) transistor comprising:
a semiconductor substrate;
source/drain regions doped with p-type impurities at a first surface portion of the substrate;
a channel region at a second surface portion of the substrate between the source/drain regions; and
a gate pattern on the channel region, the gate pattern including a gate insulation pattern and a gate conductive pattern,
wherein the gate conductive pattern includes a first conductive pattern comprising a metal-containing material, a second conductive pattern comprising metal and silicon on the first conductive pattern, and a third conductive pattern comprising polysilicon on the second conductive pattern.

15. The PMOS transistor of claim 14, wherein a metal in the first conductive pattern is substantially identical to the metal in the second conductive pattern.

16. The PMOS transistor of claim 14, wherein the second conductive pattern includes a metal silicide thin layer formed by one of a CVD process, a sputtering process and a silicidation process.

17. The PMOS transistor of claim 14, wherein the first conductive pattern has a thickness of about 30 Å to about 200 Å, the second conductive pattern has a thickness of about 20 Å to about 100 , and the third conductive pattern has a thickness of about 500 Å to about 1,500 Å.

18. The PMOS transistor of claim 14, wherein the metal-containing. material of the first conductive pattern includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

19. The PMOS transistor of claim 14, wherein the p-type impurities include boron (B).

20. The PMOS transistor of claim 14, wherein the gate insulation pattern comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof.

21. A complementary MOS (CMOS) transistor comprising:
a semiconductor substrate including a first area and a second area; and
an NMOS transistor on the first area of the substrate and a PMOS transistor on the second area of the substrate, the NMOS transistor including first source/drain regions doped with n-type impurities at a first surface portion of the first area of the substrate, a first channel region at a second surface portion of the first area of the substrate between the first source/drain regions, and a first gate pattern having a first gate insulation pattern and a first gate conductive pattern and positioned on the first channel region, and the PMOS transistor including second source/drain regions doped with p-type impurities at a first surface portion of the second area of the substrate, a second channel region at a second surface portion of the second area of the substrate between the second source/drain regions, and a second gate pattern having a second gate insulation pattern and a second gate conductive pattern and positioned on the second channel region,
wherein the first gate conductive pattern includes a first conductive pattern comprising a metal-containing material, a second conductive pattern comprising metal and silicon on the first conductive pattern, and a third conductive pattern comprising polysilicon on the second conductive pattern, and the second gate conductive pattern includes a fourth conductive pattern comprising a metal-containing material, a fifth conductive pattern comprising metal and silicon on the fourth conductive pattern and a sixth conductive pattern comprising polysilicon on the fifth conductive pattern.

22. The CMOS transistor of claim 21, wherein a metal in the first conductive pattern is substantially identical to the metal in the second conductive pattern and a metal in the fourth conductive pattern is substantially identical to the metal in the fifth conductive pattern.

23. The CMOS transistor of claim 21, wherein the second and fifth conductive patterns include a metal silicide thin layer formed by one of a CVD process, a sputtering process and a silicidation process, respectively.

24. The CMOS transistor of claim 21, wherein the first and fourth conductive patterns have a thickness of about 30 Å to about 200 Å, respectively, the second and fifth conductive patterns have a thickness of about 20 Å to about 100 Å, respectively, and the third and sixth conductive patterns have a thickness of about 500 Å to about 1,500 Å, respectively.

25. The CMOS transistor of claim 21, wherein the metal-containing material of the first and fourth conductive patterns includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof.

26. The CMOS transistor of claim 21, wherein the n-type impurities include any one selected from the group consisting of phosphorus (P), arsenic (As) and a combination thereof, and the p-type impurities include boron (B).

27. The CMOS transistor of claim 21, wherein the first and second gate insulation patterns comprise any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof, respectively.

28. A method of forming a gate structure, comprising:
forming a first conductive layer comprising a metal-containing material on a substrate;
artificially forming a second conductive layer on the first conductive layer, the second conductive layer comprising metal and silicon;
forming a third conductive layer on the second conductive layer, the third conductive layer comprising polysilicon; and
sequentially patterning the third conductive layer, the second conductive layer and the first conductive layer, thereby forming a first conductive pattern, a second conductive pattern and a third conductive pattern sequentially stacked on the substrate.

29. The method of claim 28, wherein the metal-containing material of the first conductive layer includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride,. aluminum nitride and combinations thereof, and the first conductive layer is formed to a thickness of about 30 Å to about 200 Å on the substrate by one of a CVD process, an atomic layer deposition (ALD) process and a sputtering process.

30. The method of claim 28, wherein a metal in the first conductive layer is substantially identical to the metal in the second conductive layer, and the second conductive layer includes a metal silicide thin layer formed to a thickness of about 20 Å to about 100 Å by one of a chemical vapor deposition (CVD) process, a. sputtering process and a silicidation process, respectively.

31. The method of claim 28, wherein the third conductive layer is formed to a thickness of about 500 Å to about 1,500 Å.

32. A method of forming an NMOS transistor, comprising:
forming an insulation layer on a semiconductor substrate;
forming a first conductive layer comprising a metal-containing material on the insulation layer;
artificially forming a second conductive layer on the first conductive layer, the second conductive layer comprising metal and silicon;
forming a third conductive layer on the second conductive layer, the third conductive layer comprising polysilicon;
sequentially patterning the third conductive layer, the second conductive layer and the first conductive layer, thereby forming a gate conductive pattern including a first conductive pattern, a second conductive pattern and a third conductive pattern sequentially stacked on the insulation layer;
patterning the insulation layer such that the insulation layer remains under the gate conductive pattern, so that a gate insulation pattern is formed under the gate conductive pattern, to thereby form a gate pattern including the gate insulation pattern and the gate conductive pattern on the substrate; and
forming source/drain regions at surface portions of the substrate adjacent to the gate pattern by implanting n-type impurities onto the substrate.

33. The method of claim 32, wherein the insulation layer comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof, and the insulation layer is formed on the insulation layer by one of a CVD process and an ALD process.

34. The method of claim 32, wherein the metal-containing material of the first conductive layer includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof, the first conductive layer being formed to a thickness of about 30 Å to about 200 Å by one of a CVD process, an ALD process and a sputtering process;
a metal in the first conductive layer is substantially identical to the metal in the second conductive layer, the second conductive layer including a metal silicide thin layer formed to a thickness of about 20 Å to about 100 Å by one of a chemical vapor deposition (CVD) process, a sputtering process and a silicidation process; and
the third conductive layer is. formed to a thickness of about 500 Å to about 1,500 Å.

35. The method of claim 32, wherein the n-type impurities include any one selected from the group consisting of phosphorus (P), arsenic (As) and a combination thereof.

36. A method of forming a PMOS transistor, comprising:
forming an insulation layer on a semiconductor substrate;
forming a first conductive layer comprising a metal-containing material on the insulation layer;
artificially forming a second conductive layer on the first conductive layer, the second conductive layer comprising metal and silicon;
forming a third conductive layer on the second conductive layer, the third conductive layer comprising polysilicon;
sequentially patterning the third conductive layer, the second conductive layer and the first conductive layer, thereby forming a gate conductive pattern including a first conductive pattern, a second conductive pattern and a third conductive pattern sequentially stacked on the insulation layer;
patterning the insulation layer such that the insulation layer remains under the gate conductive pattern, so that a gate insulation pattern is formed under the gate conductive pattern, to thereby form a gate pattern including the gate insulation pattern and the gate conductive pattern on the substrate; and
forming source/drain regions at surface portions of the substrate adjacent to the gate pattern by implanting p-type impurities onto the substrate.

37. The method of claim 36, wherein the insulation layer comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof, and the insulation layer is formed on the insulation layer by one of a CVD process and an ALD process.

38. The method of claim 36, wherein the metal-containing material of the first conductive layer includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof, the first conductive layer being formed to a thickness of about 30 Å to about 200 Å by one of a CVD process, an ALD process and a sputtering process;
a metal in the first conductive layer is substantially identical to the metal in the second conductive layer, the second conductive layer including a metal silicide thin layer formed to a thickness of about 20 Å to about 100 Å by one of a chemical vapor deposition (CVD) process, a sputtering process and a silicidation process; and
the third conductive layer is formed to a thickness of about 500 Å to about 1,500 Å.

39. The method of claim 36, wherein the p-type impurities include boron (B).

40. A method of forming a CMOS transistor, comprising:
forming an insulation layer on a semiconductor substrate including a first area and a second area;
forming a first conductive layer on the insulation layer, the first conductive layer comprising a metal-containing material;
artificially forming a second conductive layer on the first conductive layer, the second conductive layer comprising metal and silicon;
forming a third conductive layer on the second conductive layer, the third conductive layer comprising polysilicon;
sequentially patterning the third, second and first conductive layers, thereby forming a first gate conductive pattern including first, second and third conductive patterns sequentially stacked on the insulation layer in the first area of the substrate and a second gate conductive pattern including fourth, fifth and sixth conductive patterns sequentially stacked on the insulation layer in the second area of the substrate;
patterning the insulation layer such that the insulation layer remains under the first and second gate conductive patterns, so that a first gate insulation pattern is formed under the first gate conductive pattern and a second gate insulation pattern is formed under the second gate conductive pattern, to thereby form a first gate pattern including the first gate insulation pattern and the first gate conductive pattern in the first area of the substrate and a second gate pattern including the second gate insulation pattern and the second gate conductive pattern in the second area of the substrate;
forming first source/drain regions at surface portions of the substrate adjacent to the first gate pattern by implanting n-type impurities onto the first area of the substrate; and
forming second source/drain regions at surface portions of the substrate adjacent to the second gate pattern by implanting p-type impurities onto the second area of the substrate.

41. The method of claim 40, wherein the insulation layer comprises any one selected from the group consisting of silicon oxide, silicon oxynitride, hafnium oxide, hafnium oxynitride, hafnium silicon oxynitride, zirconium oxide, zirconium oxynitride, zirconium silicon oxynitride, tantalum oxide, tantalum oxynitride, tantalum silicon oxynitride, aluminum oxide, aluminum oxynitride, aluminum silicon oxynitride, titanium oxide, titanium oxynitride, titanium silicon oxynitride and combinations thereof, and the insulation layer is formed on the insulation layer by one of a CVD process and an ALD process.

42. The method of claim 40, wherein the metal-containing material of the first and fourth conductive layers includes any one selected from the group consisting of nickel (Ni), tungsten (W), platinum (Pt), titanium (Ti), tantalum (Ta), zirconium (Zr), copper (Cu), ruthenium (Ru), hafnium (Hf), aluminum (Al), iridium (Ir), tungsten nitride, titanium nitride, titanium aluminum nitride, hafnium nitride, hafnium aluminum nitride, tantalum nitride, tantalum aluminum nitride, zirconium nitride, zirconium aluminum nitride, aluminum nitride and combinations thereof, the first and fourth conductive layers being formed to a thickness of about 30 Å to about 200 Å by one of a CVD process, an ALD process and a sputtering process, respectively;
a metal in the first and fourth conductive layers are substantially identical to the metal in the second and fifth conductive layers, respectively, the second and fifth conductive layers including a metal silicide thin layer formed to a thickness of about 20 Å to about 100 Å by one of a chemical vapor deposition (CVD) process, a sputtering process and a silicidation process, respectively; and
the third and sixth conductive layers are formed to a thickness of about 500 Å to about 1,500 Å, respectively.

43. The method of claim 40, wherein the n-type impurities include any one selected from the group consisting of phosphorus (P), arsenic (As) and a combination thereof, and the p-type impurities include boron (B).
